(19) United States
(12) Patent Application Publication
(10) Pub. No.: US 2021/0082852 A1
(43) Pub. Date: Mar. 18, 2021

(54) COPPERLESS REGIONS TO CONTROL PLATING GROWTH

(71) Applicant: Intel Corporation, Santa Clara, CA (US)

(72) Inventors: Bradon C. MARIN, Chandler, AZ (US); Jung Kyu HAN, Chandler, AZ (US); Thomas HEATON, Mesa, AZ (US); Ali LEHAF, Phoenix, AZ (US); Rahul MANEPALLI, Chandler, AZ (US); Srinivas PIETAMBARAM, Chandler, AZ (US); Jacob VEHONSKY, Gilbert, AZ (US)

(21) Appl. No.: 16/572,354

(22) Filed: Sep. 16, 2019

(51) Int. Cl. H01L 23/00; C25D 3/38; C25D 7/12; C25D 5/02

(52) U.S. Cl. CPC H01L 24/14; H01L 24/11; H01L 24/13; C25D 3/38; H01L 2224/1403; C25D 5/022; H01L 2224/1111; H01L 2224/11462; H01L 2224/13147; C25D 7/12

(57) ABSTRACT

Embodiments of the present disclosure may generally relate to systems, apparatus, and/or processes directed to manufacturing a package having a substrate with a first side and a second side opposite the first side, where a copper layer is coupled with a first region of the first side of the substrate and includes a plurality of bumps coupled with the first region of the first side of the substrate where one or more second regions on the first side of the substrate not coupled with a copper layer, and where a layout of the one or more second regions on the first side of the substrate is to vary a growth, respectively, of each of the plurality of bumps during a plating process by modifying a local copper density of each of the plurality of bumps.

### FIELD

Embodiments of the present disclosure generally relate to the field of package assemblies, and in particular package assemblies that include plated bumps.

### BACKGROUND

Continued reduction in end product size of mobile electronic devices such as smart phones and ultrabooks is a driving force for the development of reduced-size system-in-package components that include increased bump density.

### BRIEF DESCRIPTION OF THE DRAWINGS

FIGS. 1A-1B illustrate examples of bump thickness variation (rBTV) requirements in packages, in accordance with embodiments.

FIG. 2 illustrates an example of a package assembly with different bump heights, in accordance with embodiments.

FIGS. 3A-3M illustrate examples of package assemblies with grown bump heights at various stages of a manufacturing process, in accordance with embodiments.

FIG. 4 illustrates an example of thermally decomposing sacrificial polymers used to remove copper, in accordance with embodiments.

FIGS. 5A-5B illustrate simulations of electrolytic plating rate differences, in accordance with embodiments.

FIG. 6 illustrates an example of a process to use copperless regions to control plating growth, in accordance with embodiments.

FIG. 7 schematically illustrates a computing device, in accordance with embodiments.

### DETAILED DESCRIPTION

Embodiments of the present disclosure may generally relate to systems, apparatus, and/or processes directed to manufacturing a package having a substrate with a first side and a second side opposite the first side, where a copper layer is coupled with a first region of the first side of the substrate and includes a plurality of bumps coupled with the first region of the first side of the substrate where one or more second regions on the first side of the substrate are not coupled with the copper layer, and where a layout of the one or more second regions on the first side of the substrate is to vary a growth, respectively, of each of the plurality of bumps during a plating process by modifying a local copper density of each of the plurality of bumps.

In order to increase communication bandwidth and reduce silicon area, it may be desirable to scale the bump pitch and reduce bump thickness variation in future architectures of chips and packages. For example, for EMIB bridge dies, it may be desirable to scale the bump pitch from 55 μm to 45 μm, and further to less than 30 μm. In addition, to meet projected I/O density requirements, tighter tolerance of rBTV may be required of a first level interconnect (FLI) for a die attach assembly process, for example attaching by thermal compression bonding. In addition, maintaining a bump thickness variation lower than 10 μm for assembly interactions may be desirable for future generations of package technologies.

Legacy implementations are not able to reliably approach these levels of rBTV tolerances. For example, a legacy multilayer organic substrate may have a thickness variation of greater than 40 μm even before reaching a final layer. Legacy solutions that use lithography or laser processes to control solder resist openings (SRO)/dry-film resist opening (DFRO) sizes, and subsequent bump volume and height, lack the ability to accommodate different bump volumes without multiple, expensive process techniques.

With legacy implementations, even on a flat polished surface (e.g., glass), it is very challenging to achieve uniform plated copper or tin bump height uniformity in the FLI due to the nature of the variation from via recess and metal density differences between regions with different bump pitches on the FLI layer. Furthermore, future bridging architectures, such as EMIB, will put more reliability requirements on packages to enable connection of modular dies to meet the high bandwidth die-to-die communication connection needs. This will not only drive the need for a significant decrease in rBTV at finer pitches, but also will become a significant cost driver.

Legacy approaches to meet the stringent rBTV requirements for next generation EMIB and future die tiling applications include build-up layer chemical and mechanical polishing (CMP) planarization, advanced lamination technologies, FLI layer planarization, and plating uniformity improvement. Build-up layer planarization and advanced lamination technologies are costly processes, and may require significant capital investments. FLI layer CMP planarization may be used for plated copper bumps. However, for plated solder bumps, no existing planarization slurries are currently available. FLI plating uniformity improvement is limited by the large panel size form factor as well as the small vs. large SRO pad size-induced plating height limitations post reflow.

Embodiments described herein may include use of sacrificial polymers to support temporary copper dummification, or removal areas, to improve FLI plating uniformity. These sacrificial polymers are robust enough to survive the harsh, alkaline baths encountered in backend plating (as opposed to traditional DFRs which are designed to develop or strip away in alkaline solutions, but thermally decompose under high temperatures (250-300 degrees C.)), and are photo-definable. These qualities make these sacrificial polymers useful for selective dummification as well as a number of other applications in semiconductor packaging. Embodiments described herein may modulate the height of fabricated bumps without the need for extra lithography or wet techniques. Implementation of embodiments described herein may reduce the chance for yield loss by bump misalignment, thus resulting in tighter bump tolerances and ultimately higher performing products.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

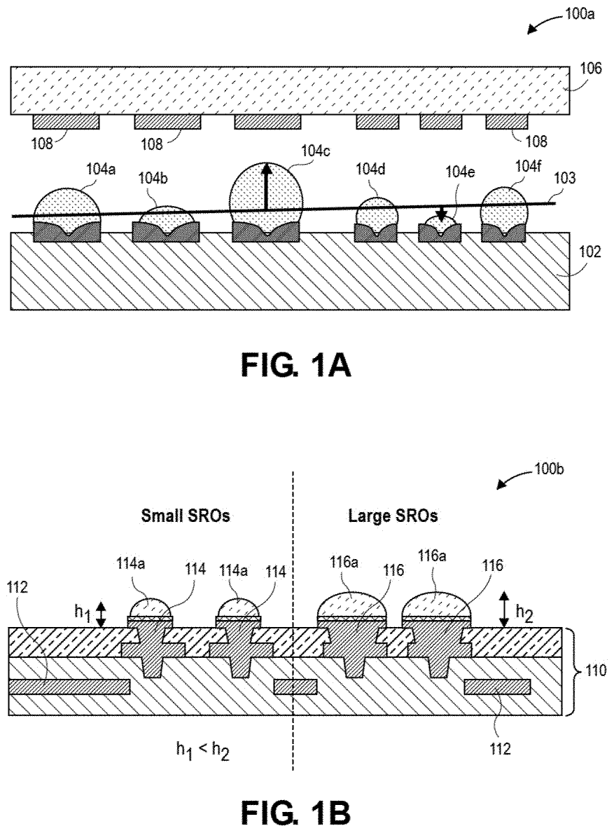

FIGS. 1A-1B illustrate examples of bump thickness variation (rBTV) requirements in packages, in accordance with embodiments. FIG. 1A includes diagram 100a that shows an example of a package that shows challenges of rBTV requirements for a thermo-compression bonding (TCB) assembly process. A substrate 102, which may be an organic substrate, has a plurality of bumps 104a-104f attached that are of various sizes and heights above the substrate 102. In embodiments, the substrate 102 may represent a FLI package. The various sizes and heights of the bumps 104a-104f may be due to thickness level variation in the substrate 102, warpage on the substrate 102, variations from via recesses and metal density differences with the different bump pitches for the bumps 104a-104f. These variations in size and height of the bumps 104a-104f make it a challenge to connect with another die 106, such as an EMIB 106 having various pads 108 of substantially even height with respect to the die 106. This may be particularly true when small pitches are involved. As pitches and bump sizes decrease, the resulting opening in the SRO can decrease as well, changing the volume for the bump. As shown in FIG. 1A, this results in variable heights for the bumps, which lead to an offset in assembly. The sloping line 103 highlights that the flat surface of the package cannot accommodate the variable heights of the organic substrate, and highlights a need for bump planarity for future pitch scaling.

FIG. 1B includes diagram 100b that shows an example of a package highlighting the post reflow BTV differences induced by different bump pitches and FLI panel level plating limitations. Substrate 110 may include multiple layers that include traces 112 as well as small solder resist openings (SRO) 114 and large SROs 116. The small SROs 114 result in lower height (h₁) bumps 114a and larger SROs 116 resulting in taller height (h₂) bumps 116a using legacy processes. Thus, variable SRO 114, 116 sizes lead to variable bump volumes, which lead to variable bump heights.

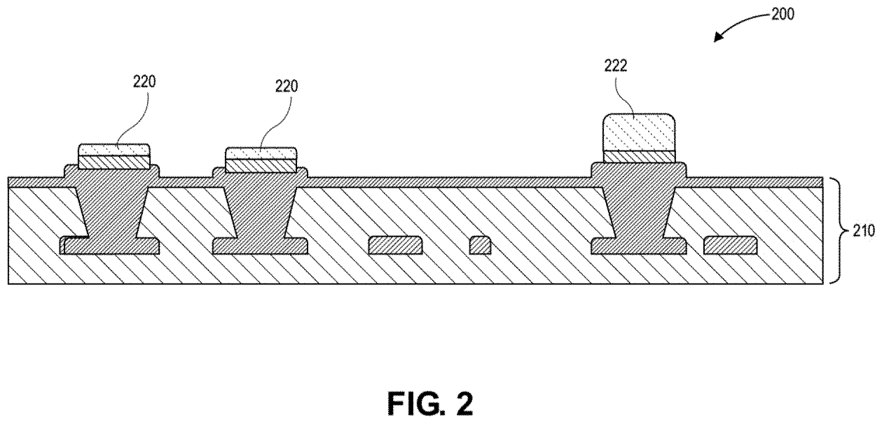

FIG. 2 illustrates an example of a package assembly with different bump heights, in accordance with embodiments. FIG. 2 includes diagram 200 that includes a substrate 210 that include bumps 220 of a first height above the substrate 210, and bump 222 of a second height above the substrate 210 that are created using the techniques described below. In this way, specific height of bumps may be leveled, such as bumps 220, or may be created using a specific height difference, such as bumps 220, 222. In this way, connections to different dies (not shown) having different thicknesses may be attached to the various bumps 220, 222 with high quality connection and with a high bump pitch.

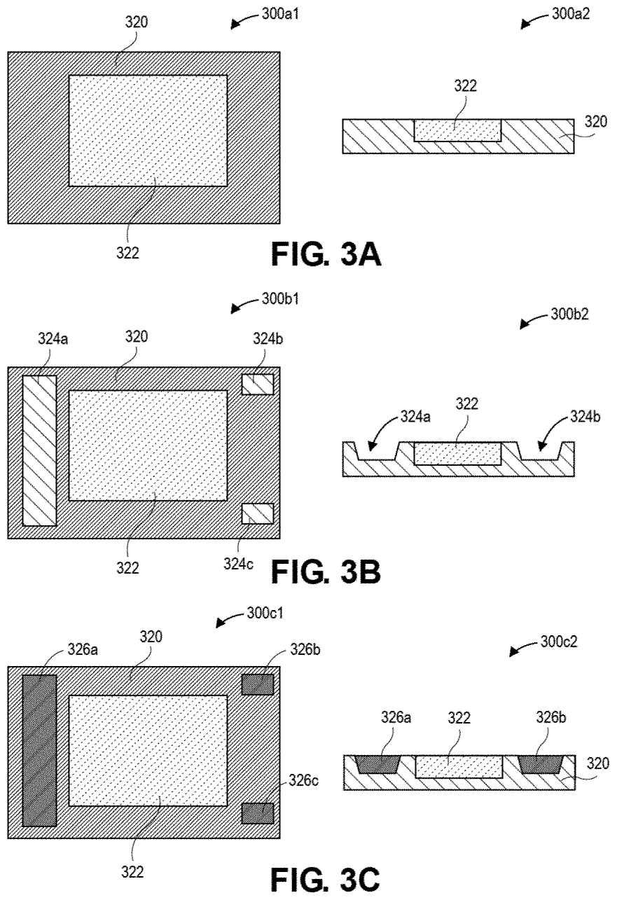

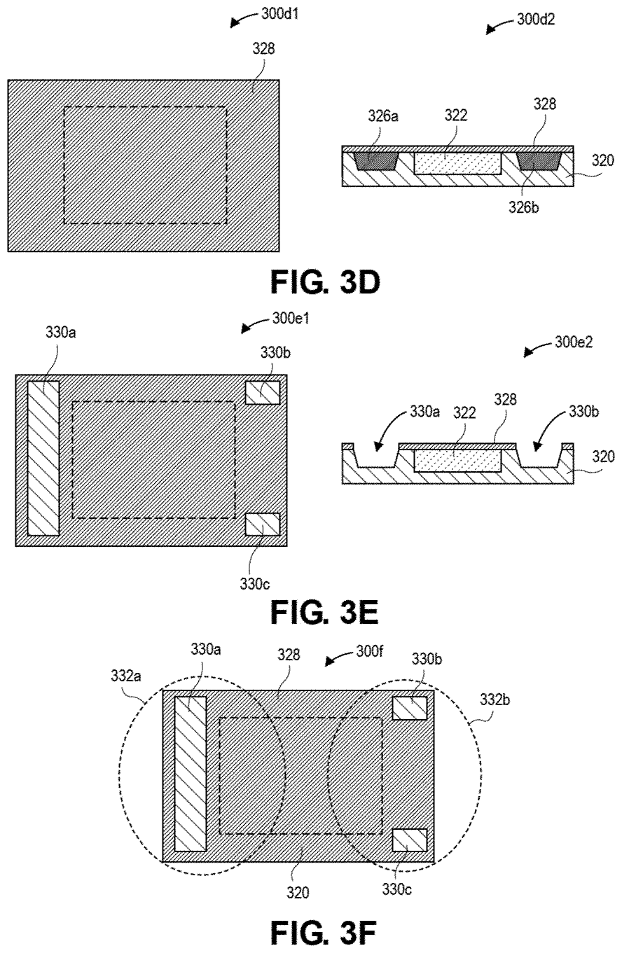

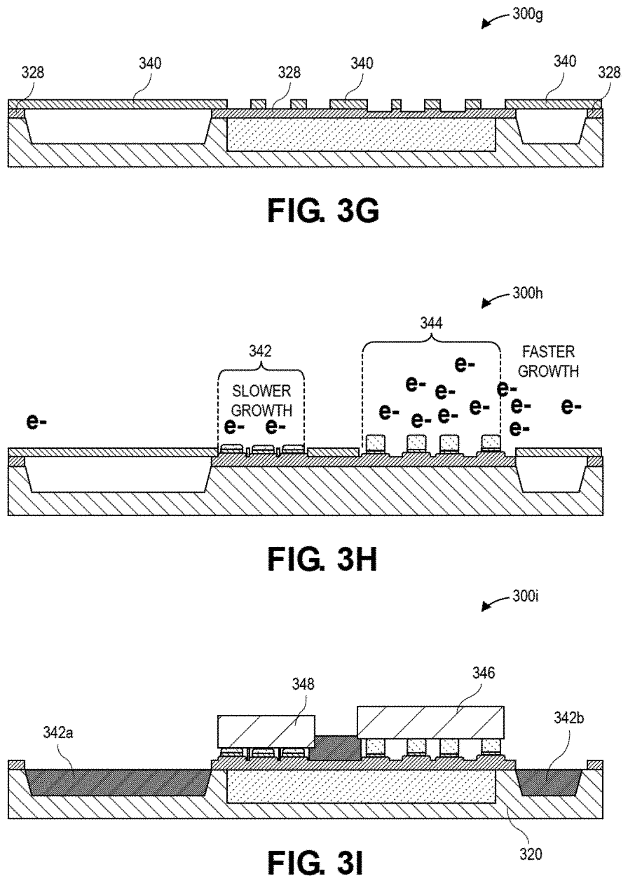

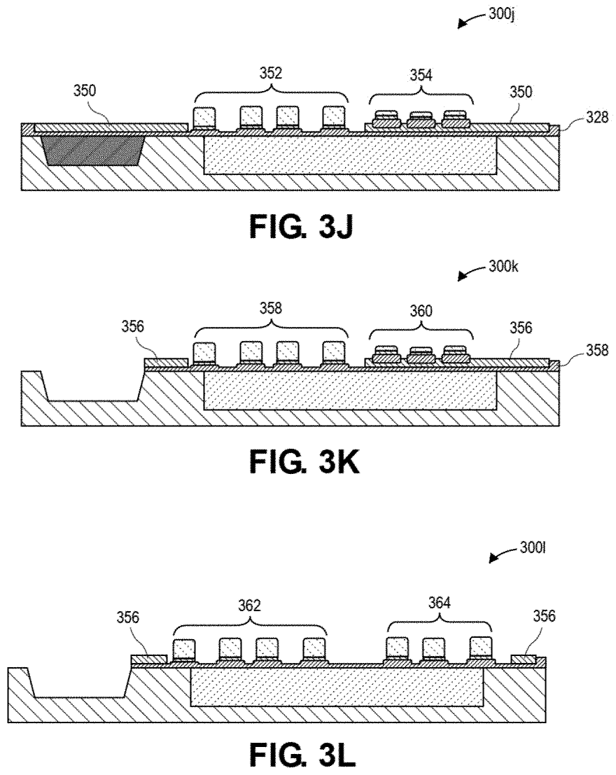

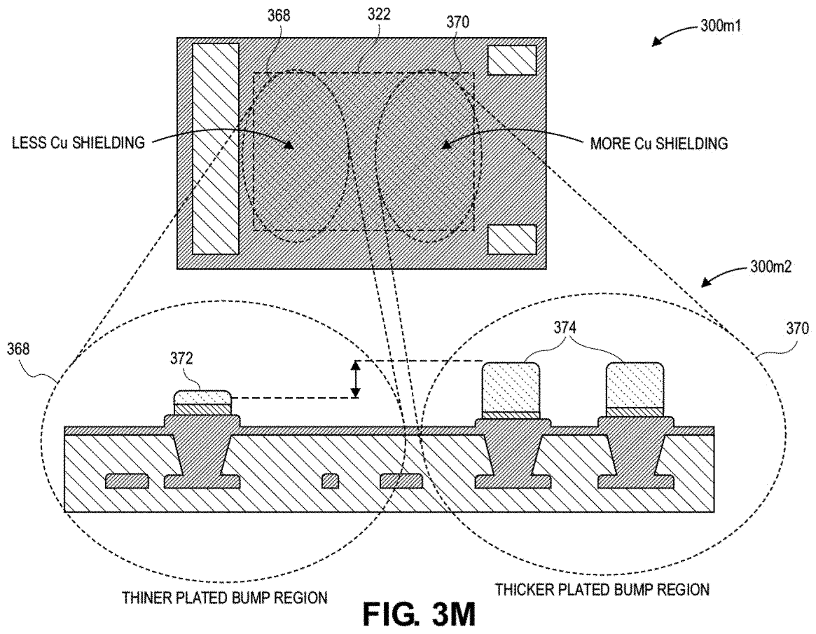

FIGS. 3A-3M illustrate examples of package assemblies with grown bump heights at various stages of a manufacturing process, in accordance with embodiments. FIG. 3A includes diagram 300a1 that shows a top-down view of a substrate 320 that includes an active area 322 that is defined on the substrate 320. The active area 322 may be an area onto which various bumps are to be plated. Diagram 300a2 shows a cross-section view of the substrate 320 and of the active area 322. In embodiments, the substrate 320 may be part of a FLI or organic substrate. The substrate 320 may also be a multitude of laminate epoxy layers, with or without a glass cloth-impregnated core.

FIG. 3B includes diagram 300b1, which may be similar to diagram 300a1, but with volumes 324a, 324b, 324c removed from the substrate 320. In embodiments, the volumes 324a, 324b, 324c may be outside of the active area 322. In embodiments, other volume areas may also be removed depending upon the desired speed of bump plating elsewhere on the active area 322. In embodiments, the removal may be accomplished through a drilling process, laser or mechanical, or may be accomplished through skiving. The volumes 324a, 324b, 324c identify areas that subsequently will not include copper plating when the subsequent bump plating process occurs. Diagram 300b2 shows a cross-section view of the substrate 320 and the active area 322, with the volumes 324a and 324b removed.

FIG. 3C includes diagram 300c1, which may be similar to diagram 300b1, but where volumes 324a, 324b, 324b have been filled with a sacrificial polymer 326a, 326b, 326c respectively. Diagram 300c2 shows a side cross-section that include sacrificial polymer 326a, 326b. In embodiments, the sacrificial polymer 326a, 326b, 326c is at a level of a side of the package 320, and can be filled in the substrate by using a stencil process or by lamination and subsequent planarization.

FIG. 3D includes diagram 300d1, which may be similar to diagram 300c1, where a layer of copper 328 has been applied to the top of the substrate 320 and the sacrificial polymer 326a, 326b, 326c. Diagram 300d2 shows a cross-section of the package 320 where the copper layer 328 is applied over the substrate 320, the sacrificial polymer 326a, 326b, 326c, and the active area 322.

FIG. 3E includes diagram 300e1, which may be similar to diagram 300d1, where substrate 320 has been heated to a sufficient temperature to cause a thermal process within the sacrificial polymer 326a, 326b, 326c to cause the sacrificial polymer to degass and to remove the copper layer 328 adjacent to the sacrificial polymer 326a, 326b, 326c. As a result, the cavities 330a, 330b, 330c are created that have no copper layer 328. Diagram 300e2 shows a cross-section of the package 320, with the cavities 330a, 330b that have no copper layer 328.

FIG. 3F includes diagram 300f that is top-down view of the package that highlights two areas 332a, 332b of the package. The first area 332a, that is proximate to the volume 330a that represents a substantially larger removed area of the copper plating 328. As a result, there is less copper shielding in the first area 332a and therefore any plating done in the active area 320 within the first area 332a will result in less plating, and/or slower growth of plating of bumps. This is in contrast to the second area 332b, that is proximate to the volumes 330b, 330c that represent a substantially smaller removed area of the copper plating 328. As a result, there is more copper shielding in the second area 332b, and therefore any plating done in the active area 320 within the second area 332b will result in more plating, and/or faster growth of plating of bumps that the first area 332a. As described further below, this effect is due to the density of surface electrons upon the layer of copper 328 that are available during plating. As used herein the term copper shielding may be used to describe sacrificial copper that is not intended for use as a trace or power plane and the term copper plating may be used for all plated copper—whether for shielding or traces and power planes.

FIG. 3G includes diagram 300g that is a cross-section of package, which may be similar to the package of diagram 300e1 of FIG. 3E, and shows an action in a subsequent plating process. In embodiments, a patterned solder resist layer 340 may be placed on the copper layer 328. The pattern solder resist layer 340 identifies a pattern for subsequent bump growth.

FIG. 311 includes diagram 300h that is a cross-section of the package, which may be similar to package of diagram 300g of FIG. 3G. As shown, plated bumps 342 will grow at a slower rate than the plated bumps 344. This is due to more copper increasing the density of electrons proximate to the copper and more electrons will result in a faster plating rate because the electrons are the reducing agents to grow the higher bumps 344. Less growth will occur in bumps 342 where there is less surrounding copper. This effect involves the surface area of the surrounding copper and affects the surface area kinetics where the more surface area of copper the more free electrons are on the surface of the copper. As a result, different bump heights will result from different growth rates. This may be used to grow higher bumps or to level out bumps as described further below.

FIG. 31 includes diagram 300i, where a first die 346 may be coupled with the taller plated bumps 344, and a second die 348 may be coupled with the shorter bumps 342. The solder resist 340 may be removed, and the volumes 342a, 342b may be filled with another material to provide rigidity to the substrate 320. Additionally, filling the volumes 342a, 342b allows for matching of coefficient of thermal expansion (CTE) of the composite substrate, which allows for warpage to be avoided during reliability testing and operation. For example, if the substrate is projected to be in a high-stress state (due to CTE mismatching in layers), then the volumes can be filled with a low glass transition temperature polymer to dissipate stress.

FIG. 3J includes diagram 300j, which may be similar to diagram 300g of FIG. 3G, showing an example of a solder resist pattern 350 is placed evenly on top of a copper layer 328 that has not been removed, to cause an even set of growth between a first set of taller bumps 352 and a second set of shorter bumps 354.

FIG. 3K includes diagram 300k, which may be similar to diagram 300j of FIG. 3J, showing an example of a different solder resist pattern 356 placed over a copper layer 358 where the left side of copper has been removed. During plating, slower growth will occur on the taller set of plated bumps 358 versus a faster growth on the shorter set of bumps 360.

FIG. 3L includes diagram 300l, which may be similar to diagram 300k of FIG. 3K, showing the result of plating where the previous set of taller bumps 362 are now at a same height of the previous shorter set of bumps 364. The right side of bumps 364 has caught up due to a faster plating rate due to more copper on the right side of the package during plating than on the left side. The result is bump planarization by selective chemical plating.

FIG. 3M includes diagram 300m1, which may be similar to diagram 300f of FIG. 3F, identifying two regions proximate to active area 322, a lesser copper shielding area 368 and a greater copper shielding area 370. Diagram 300m2 shows corresponding areas on a cross-section of the package, which may be similar to diagram 200 of FIG. 2, where the reduced copper shielding areas 368 result in a lower bump 372 height and the increased copper shielding areas 370 result in a greater bump height 374.

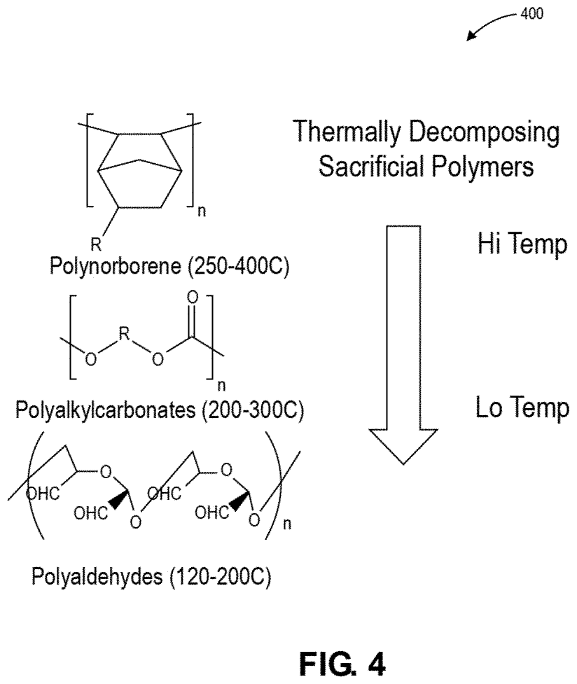

FIG. 4 illustrates an example of thermally decomposing sacrificial polymers used to remove copper, in accordance with embodiments. Diagram 400 shows a graphic example of the chemical compound of thermally decomposing sacrificial polymers and the respective temperatures at which they break down. This includes Polynorborene (240-400 degrees Celsius), Polyalkylcarbonates (200-300 degrees Celsius), and Polyaldehydes (120-200 degrees Celsius). In embodiments, acrylates and quinones can be added to sacrificial polymer blends to make them photodefinable. It should be noted that the alkaline robustness of these polymers makes them useful for various other photo-definable processes, such as backend bump plating. Additionally, high-pressure water (HPW) rinse or other cleaning process may be used after thermal decomposition to remove the degassed copper, polymer residue, and debris.

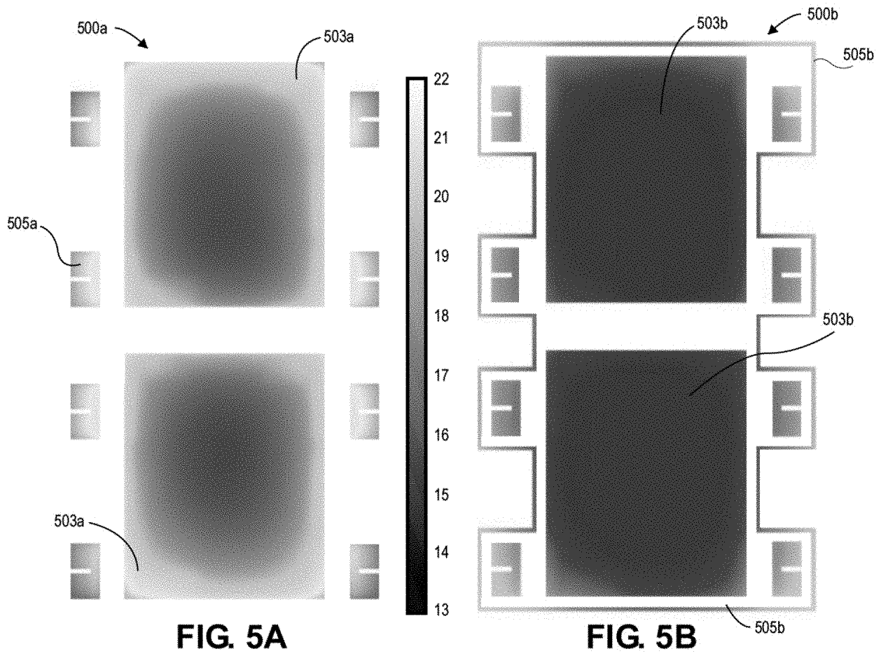

FIGS. 5A-5B illustrate simulations of electrolytic plating rate differences, in accordance with embodiments. Diagram 500a shows an output of the simulation that illustrates the effect of electrolytic plating without copper shielding on the border. As a result, in FIG. 5A without the copper shielding on the border there is a distribution in bump height (dark areas 503b indicate high bump height and light areas 503a indicate low bump height). The bump height is higher in the center of the unit due to the high copper density and resulting high charge density. Conversely, the periphery of the unit is low in bump height due to a low copper density.

Diagram 500b shows an output of the simulation that illustrates the effect of electrolytic plating with copper shielding on the border. As a result, in FIG. 5B, the addition of the copper shielding 505b on the border allows for charge to accumulate at the periphery of the unit and increase the plating rate of the unit edges. Note that the unit edges 505a in FIG. 5A are the shallow points in bump height. Increasing the plating rate of the unit edges in FIG. 5B by adding copper shielding 505b provides for a more uniform bump height as shown.

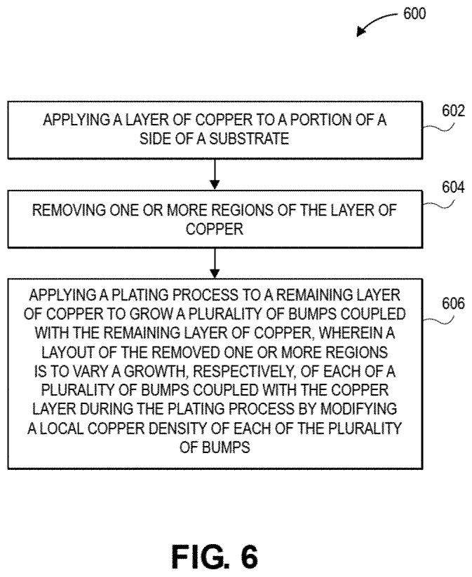

FIG. 6 illustrates an example of a process to use copperless regions to control plating growth, in accordance with embodiments. Process 600 may be performed by one or more elements, techniques, or systems that may be found in FIG. 1A-5B, and related to diagrams 100a, 100b, 200, 300a1, 300a2, 300b1, 300b2, 300c1, 300c2, 300d1, 300d2, 300e1, 300e2, 300f, 300g, 300h, 300i, 300j, 300k, 300l, 300m1, 300m2, 400, 500a, 500b.

At block 602, the process may include applying a layer of copper to a portion of the side of a substrate. In embodiments, the layer of copper may correspond to copper layer 328 of FIGS. 3D-3F, and copper layer 328 of FIG. 3K. In embodiments, applying the layer of copper may include using a plating process on top of a substrate, such as substrate 320 of FIG. 3A.

At block 604, the process may further include removing one or more regions of the layer of copper. In embodiments, the regions of copper to be removed may correspond to the region of copper proximate to sacrificial polymer 326a, 326b, 326c of FIG. 3D. In embodiments, the copper may be removed by heating the sacrificial polymer above the temperature so that the polymer degasses and removes the copper that was plated onto the sacrificial polymer.

At block 606, the process may further include applying a plating process to a remaining layer of copper to grow a plurality of bumps coupled with the remaining layer of copper, wherein a layout of the removed one or more regions is to vary a growth, respectively, of each of a plurality of bumps coupled with the copper layer during the plating process by modifying a local copper density of each of the plurality of bumps. In embodiments, the plating process may be similar to the plating process described at block 604 after a solder resist mask, such as mask 340 of FIG. 3G, is applied to the package. Modifying the local copper density of each of the plurality of bumps may be found in the process identified with FIGS. 3B-3E where sacrificial polymer 326a, 326b, 326c is inserted into recesses 324a, 324b, 324c, plated over with copper 328. In addition, portions of the copper are removed via sacrificial polymer degassing, resulting in various areas of copper on the package having less surrounding copper 332a causing slower plating in or near the area, and various areas of copper on the package having more surrounding copper 332b causing faster plating. It should be appreciated that one or more actions of this process may be performed at any time with respect to the package manufacture process.

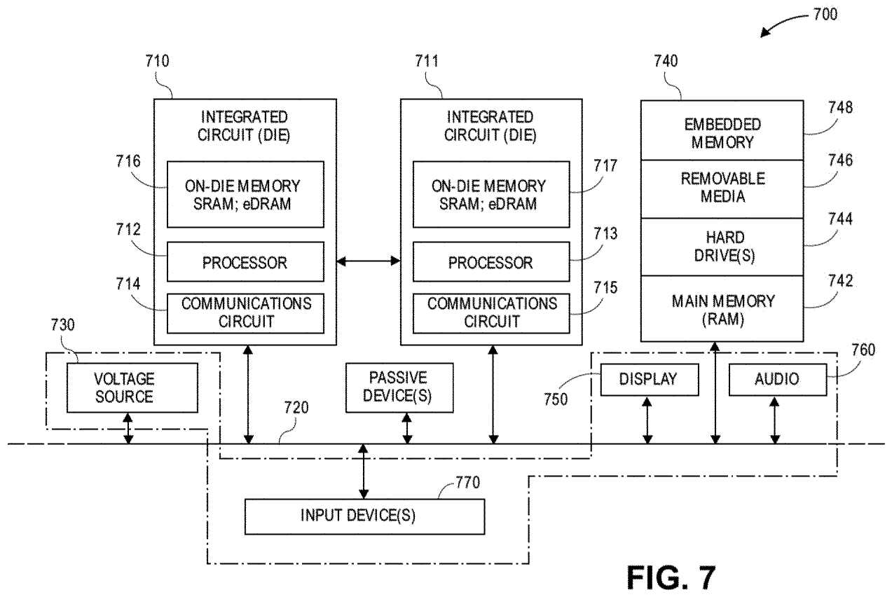

FIG. 7 is a schematic of a computer system 700, in accordance with an embodiment of the present invention. The computer system 700 (also referred to as the electronic system 700) as depicted can embody copperless regions to control plating growth, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, copperless regions to control plating growth, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a package substrate having copperless regions to control plating growth, according to any of the several disclosed embodiments and their equivalents, an electronic system, a computer system, one or more methods of fabricating an integrated circuit, and one or more methods of fabricating an electronic assembly that includes a package substrate having copperless regions to control plating growth, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having copperless regions to control plating growth embodiments and their equivalents. A foundation substrate may be included, as represented by the dashed line of FIG. 7. Passive devices may also be included, as is also depicted in FIG. 7.

### Examples

The following paragraphs describe examples of various embodiments.

Example 1 includes a package comprising: a substrate with a first side and a second side opposite the first side; a copper layer coupled with a first region of the first side of the substrate; a plurality of bumps coupled with the first region of the first side of the substrate; one or more second regions on the first side of the substrate not coupled with a copper layer; and wherein a layout of the one or more second regions on the first side of the substrate is to vary a growth, respectively, of each of the plurality of bumps during a plating process by modifying a density of copper, respectively, proximate to each of the plurality of bumps.

Example 2 includes the package of example 1, wherein the one or more second regions on the first side of the substrate further includes: one or more volumes, respectively, proximate to the one or more second regions that extend into the substrate.

Example 3 includes the package of example 2, wherein the one or more volumes includes a fill material.

Example 4 includes the package of example 3, wherein the fill material includes a polymer.

Example 5 includes the package of example 3, wherein the fill material and a material of the substrate are different materials.

Example 6 includes the package of example 1, wherein each bump of the plurality of bumps is at substantially a same height with respect to a plane of the substrate.

Example 7 includes the package of example 1, wherein each bump in a first set of the plurality of bumps is at substantially a first height with respect to a plane of the substrate, and wherein each bump in a second set of the plurality of bumps is at substantially a second height with respect to the plane.

Example 8 includes the package of example 7, further comprising a first die coupled with the first set of the plurality of bumps; and a second die coupled with the second set of the plurality of bumps.

Example 9 includes the package of any one of examples 1-8, wherein the plating process is a copper plating process.

Example 10 is a process, comprising: applying a layer of copper to a portion of a side of a substrate; removing one or more regions of the layer of copper; and applying a plating process to a remaining layer of copper to grow a plurality of bumps coupled with the remaining layer of copper, wherein a layout of the removed one or more regions is to vary a growth, respectively, of each of the plurality of bumps coupled with the remaining layer of copper during the plating process by modifying a density of copper, respectively, proximate to each of the plurality of bumps.

Example 11 includes the process of example 10, further comprising, before applying the layer of copper: removing one or more volumes, respectively, of a material of the substrate proximate to the one or more regions of the layer of copper to create one or more cavities in the substrate; and filling the one or more cavities with a polymer.

Example 12 includes the process of example 11, wherein removing the one or more volumes of the material of the substrate further includes a selected one of skiving or drilling the one or more volumes of the material of the substrate.

Example 13 includes the process of example 10, wherein removing one or more regions of the layer of copper further includes heating the substrate to cause a polymer coupled with the one or more regions of the layer of copper to degass.

Example 14 includes the process of any one of examples 10-13, wherein the layout is determined based upon computer simulation.

Example 15 is a system, comprising: a circuit board; a package coupled with the circuit board, the package including: a substrate with a first side and a second side opposite the first side; a copper layer coupled with a first region of the first side of the substrate; a plurality of bumps coupled with the first region of the first side of the substrate; one or more second regions on the first side of the substrate not coupled with a copper layer; and wherein a layout of the one or more second regions on the first side of the substrate is to vary a growth, respectively, of each of the plurality of bumps during a plating process by modifying a density of copper, respectively, proximate to each of the plurality of bumps.

Example 16 includes the system of example 15, wherein the one or more second regions on the first side of the substrate further includes: one or more volumes, respectively, proximate to the one or more second regions and extending into the substrate.

Example 17 includes the system of example 16, wherein the one or more volumes includes a polymer.

Example 18 includes the system of any one of examples 16-17, wherein each bump of the plurality of bumps is at substantially a same height with respect to a plane.

Example 19 includes the system of example 18, wherein each bump in a first set of the plurality of bumps is at substantially a first height with respect to a plane, and wherein each bump in a second set of the plurality of bumps is at substantially a second height with respect to the plane.

Example 20 includes the system of example 19, further comprising a first die coupled with the first set of the plurality of bumps; and a second die coupled with the second set of the plurality of bumps.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A package comprising:
a substrate with a first side and a second side opposite the first side;
a copper layer coupled with a first region of the first side of the substrate;
a plurality of bumps coupled with the first region of the first side of the substrate;
one or more second regions on the first side of the substrate not coupled with the copper layer; and
wherein a layout of the one or more second regions on the first side of the substrate is to vary a growth, respectively, of each of the plurality of bumps during a plating process by modifying a density of copper, respectively, proximate to each of the plurality of bumps.

2. The package of claim 1, wherein the one or more second regions on the first side of the substrate further includes: one or more volumes, respectively, proximate to the one or more second regions that extend into the substrate.

3. The package of claim 2, wherein the one or more volumes includes a fill material.

4. The package of claim 3, wherein the fill material includes a polymer.

5. The package of claim 3, wherein the fill material and a material of the substrate are different materials.

6. The package of claim 1, wherein each bump of the plurality of bumps is at substantially a same height with respect to a plane of the substrate.

7. The package of claim 1, wherein each bump in a first set of the plurality of bumps is at substantially a first height with respect to a plane of the substrate, and wherein each bump in a second set of the plurality of bumps is at substantially a second height with respect to the plane.

8. The package of claim 7, further comprising a first die coupled with the first set of the plurality of bumps; and a second die coupled with the second set of the plurality of bumps.

9. The package of claim 1, wherein the plating process is a copper plating process.

10. A process, comprising:
applying a layer of copper to a portion of a side of a substrate;
removing one or more regions of the layer of copper; and
applying a plating process to a remaining layer of copper to grow a plurality of bumps coupled with the remaining layer of copper, wherein a layout of the removed one or more regions is to vary a growth, respectively, of each of the plurality of bumps coupled with the remaining layer of copper during the plating process by modifying a density of copper, respectively, proximate to each of the plurality of bumps.

11. The process of claim 10, further comprising, before applying the layer of copper:
removing one or more volumes, respectively, of a material of the substrate proximate to the one or more regions of the layer of copper to create one or more cavities in the substrate; and
filling the one or more cavities with a polymer.

12. The process of claim 11, wherein removing the one or more volumes of the material of the substrate further includes a selected one of skiving or drilling the one or more volumes of the material of the substrate.

13. The process of claim 10, wherein removing one or more regions of the layer of copper further includes heating the substrate to cause a polymer coupled with the one or more regions of the layer of copper to degass.

14. The process of claim 10, wherein the layout is determined based upon computer simulation.

15. A system, comprising:
a circuit board;
a package coupled with the circuit board, the package including:
a substrate with a first side and a second side opposite the first side;
a copper layer coupled with a first region of the first side of the substrate;
a plurality of bumps coupled with the first region of the first side of the substrate;
one or more second regions on the first side of the substrate not coupled with the copper layer; and
wherein a layout of the one or more second regions on the first side of the substrate is to vary a growth, respectively, of each of the plurality of bumps during a plating process by modifying a density of copper, respectively, proximate to each of the plurality of bumps.

16. The system of claim 15, wherein the one or more second regions on the first side of the substrate further includes: one or more volumes, respectively, proximate to the one or more second regions and extending into the substrate.

17. The system of claim 16, wherein the one or more volumes includes a polymer.

18. The system of claim 16, wherein each bump of the plurality of bumps is at substantially a same height with respect to a plane.

19. The system of claim 18, wherein each bump in a first set of the plurality of bumps is at substantially a first height with respect to a plane, and wherein each bump in a second set of the plurality of bumps is at substantially a second height with respect to the plane.

20. The system of claim 19, further comprising a first die coupled with the first set of the plurality of bumps; and a second die coupled with the second set of the plurality of bumps.
